(19) United States
(12) Patent Application Publication
(10) Pub. No.: US 2017/0236973 A1
(43) Pub. Date: Aug. 17, 2017

(54) PACKAGING METHOD FOR ULTRAVIOLET LIGHT EMITTING DIODE

(71) Applicant: Unistars Corporation, Hsinchu County (TW)

(72) Inventors: WEN-CHENG CHIEN, Hsinchu City (TW); SHANG-YI WU, Hsinchu City (TW)

(21) Appl. No.: 15/255,160

(22) Filed: Sep. 2, 2016

(30) Foreign Application Priority Data
Feb. 16, 2016 (TW) 105104503

(51) Int. Cl. H01L 33/00; H01L 33/52; H01L 33/20

(52) U.S. Cl. CPC H01L 33/0095; H01L 33/20; H01L 33/52

(57) ABSTRACT

The invention provides a packaging method for ultraviolet light emitting diode, comprising: (S1) providing a carrier, connected to an electrode; (S2) fixing an UV LED chip on the carrier and electrically connecting the UV LED chip to the electrodes; (S3) covering the UV LED chip with transparent silicon-and-oxygen-containing solution; and (S4) performing a thermal curing process.

### FIELD OF THE INVENTION

The present invention is related to a packaging method for light emitting diode (LED), especially a packaging method for ultraviolet LED (UV LED).

### BACKGROUND OF THE INVENTION

A light emitting diode (LED) is a semiconductor light source and has benefits of energy conservation, low electrical power consumption, higher efficiency, shorter activation time, longer service life, mercury free, environmental protection, and etc. And thus, LED has been widely used in lighting. In order to increase service life of LED, LED is packaged for better protection. Not only materials of a LED package structure are limited (i.e. transparent material is required for light emitting), but also structures and packaging methods are essential.

In a conventional packaging technique, a LED chip is fixed on a patterned non-transparent substrate and electrically connected to the substrate via metal wires. Transparent material is then disposed and covers the entire chip, the metal wires, and the substrate; and afterward, a curing process is performed to finish packaging process. Transparent materials are required for light emitting in a LED package, and thus choices of materials used in the LED package are very limited. Conventionally, it uses transparent polymer materials, such as epoxy resin and/or benzene-containing pure siloxane, in packaging; however, it faces problems of degradation

Epoxy resin, which is of a lower cost and easily processing material and can provide good protection to a LED chip after curing, is widely used in LED packaging. However, it is not a suitable material for high power LED chip packaging because its thermal stability is not sufficient enough and its characteristic stress is too high after curing. On the other hand, although benzene-containing pure siloxane is easy to process and has good light transparency and thermal stability and good protection after packaging, it will degrade after being exposed under ultraviolet light (wavelength less than 420 nm). Benzene rings of pure siloxane that have been exposed under light having short wavelength can lead to material degradation and embrittlement. Thus, benzene-containing pure siloxane cannot be used in packages of light source having shorter wavelength, especially for LED having wavelength less than 365 nm, or packages is going to loss protection to LED chips after a certain period of time. Therefore, service life of a lighting device or element is reduced due to the loss of protection to the LED chip leading to damages of the LED chip.

How to improve packaging method for a UV LED chip in order to improve protection and avoid material degradation becomes the subject of the present invention.

### SUMMARY OF THE INVENTION

The present invention provides a packaging method of ultraviolet light emitting diode, comprising: (S1) providing a carrier, connected to an electrode; (S2) fixing a UV LED chip onto the carrier and electrically connecting the UV LED chip to the electrodes; (S3) covering the UV LED chip with transparent silicon-and-oxygen-containing solution; and (S4) performing a thermal curing process.

In one embodiment of the present invention, wherein the transparent silicon-and-oxygen-containing solution is made of spin-on glass (SOG).

In one embodiment of the present invention, wherein the step (S3) comprises: (S3A) dispensing the transparent silicon-and-oxygen-containing solution onto the carrier to cover the UV LED chip; and (S3B) spinning the carrier to make the transparent silicon-and-oxygen-containing solution completely covering the carrier, the UV LED chip, and the electrode. And then the step (S4) is performed under a temperature condition in a range of 300˜600° C. in order to cure the transparent silicon-and-oxygen-containing solution.

In one embodiment of the present invention, after the step (S1) and before the (S2), further comprising: forming a dielectric layer covering a portion of the electrode and exposing a portion of the electrode.

In one embodiment of the present invention, wherein the step (S3) comprises: (53A′) dispensing the transparent silicon-and-oxygen-containing solution onto the carrier to cover the UV LED chip; and (S3B′) spinning the carrier to make the transparent silicon-and-oxygen-containing solution completely covering the carrier, the UV LED chip, and the exposed portion of the electrode. And then the step (S4) is performed under a temperature condition in a range of 300˜600° C. in order to cure the transparent silicon-and-oxygen-containing solution.

In one embodiment of the present invention, wherein the step (S3) comprises: (S3a) dispensing the transparent silicon-and-oxygen-containing solution onto the carrier to cover the UV LED chip; and (S3b) spinning the carrier to make the transparent silicon-and-oxygen-containing solution completely covering the UV LED chip and the exposed portion of the electrode.

In one embodiment of the present invention, wherein the UV LED chip is a flip chip comprises a chip electrode electrically connected to the electrode by direct contact.

In one embodiment of the present invention, wherein the silicon-and-oxygen-containing solution conformally covers the UV LED chip and the exposed portion of the electrode and exposes a portion of the dielectric layer.

In one embodiment of the present invention, wherein the silicon-and-oxygen-containing solution is flattened and completely covers the dielectric layer.

In one embodiment of the present invention, wherein the UV LED chip is electrically connected to the electrode by a metal wire and the silicon-and-oxygen-containing solution is flattened and completely covers the metal wire after the sub-step (S3b).

In one embodiment of the present invention, wherein the step (S3) comprises: (S3a′) dispensing the transparent silicon-and-oxygen-containing solution onto the carrier to cover the UV LED chip; and (S3b′) performing a molding process to flatten the transparent thermosetting silicon-and-oxygen-containing solution and make the transparent thermosetting silicon-and-oxygen-containing solution completely covering the carrier, the UV LED chip and the electrode.

In one embodiment of the present invention, wherein the UV LED chip is a flip chip.

In one embodiment of the present invention, wherein the UV LED chip is electrically connected to the electrode by a metal wire and the silicon-and-oxygen-containing solution is completely covering the metal wire after the sub-step (S3b′).

In one embodiment of the present invention, wherein in the step (S1), a cavity structure is disposed on the carrier exposing a portion of the electrode.

In one embodiment of the present invention, wherein after the step (S1) and before the (S2), further comprising: forming a dielectric layer covering a top surface and an inner surface of the wall structure.

In one embodiment of the present invention, wherein the step (S3) is performed by only dispensing the transparent silicon-and-oxygen-containing solution onto the UV LED chip to form a convex or dome-like structure of the transparent silicon-and-oxygen-containing solution covering the UV LED chip, the exposed portion of the electrode and the cavity structure.

In one embodiment of the present invention, wherein the step (S3) comprises: (S3a″) dispensing the transparent silicon-and-oxygen-containing solution onto the carrier to cover the UV LED chip and the cavity structure; and (S3b″) spinning the carrier to flatten the transparent thermosetting silicon-and-oxygen-containing solution and make the transparent silicon-and-oxygen-containing solution completely covering the carrier, the UV LED chip, the electrode, and the cavity structure.

In one embodiment of the present invention, wherein the UV LED chip is a flip chip.

In one embodiment of the present invention, wherein the UV LED chip is electrically connected to the electrode by a metal wire and the silicon-and-oxygen-containing solution is completely covers the metal wire after the sub-step (S3b″).

In one embodiment of the present invention, wherein the step (S3) comprises: (S3a′″) dispensing the transparent silicon-and-oxygen-containing solution onto the carrier to cover the UV LED chip and the wall structure; and (S3b′″) performing a molding process to flatten the transparent silicon-and-oxygen-containing solution and make the transparent silicon-and-oxygen-containing solution completely covering the carrier, the UV LED chip, the electrode, and the cavity structure.

In one embodiment of the present invention, wherein the UV LED chip is a flip chip.

In one embodiment of the present invention, wherein the UV LED chip is electrically connected to the electrode by a metal wire and the silicon-and-oxygen-containing solution is completely covering the metal wire after the sub-step (S3b′″).

In one embodiment of the present invention, wherein the step (S4) is performed under a temperature condition in a range of 300˜600° C.

Accordingly, the present invention provides a packaging method for UV LED, which is suitable for any conventional LED chip with common ranges of wavelengths, especially for UV LED chip with wavelength less than 365 nm. The present invention provides the packaging method is able to avoid degradation problems resulted by the conventional packaging method and thus improve service life of a UV LED chip.

### BRIEF DESCRIPTION OF THE DRAWINGS

The present invention will become more readily apparent to those ordinarily skilled in the art after reviewing the following detailed description and accompanying drawings, in which:

FIG. 1 is a flow chart according to the method provided by the present invention;

FIGS. 2A-2E are cross-sectional views of different steps according to an embodiment following the method provided by the present invention;

FIG. 3 is a cross-sectional view according to an embodiment of the present invention;

FIG. 4 is a cross-sectional view according to an embodiment of the present invention;

FIGS. 5A-5D are cross-sectional views of different steps according to an embodiment following the method provided by the present invention;

FIG. 6 is a cross-sectional view according to an embodiment of the present invention; and

FIG. 7 is a cross-sectional view according to an embodiment of the present invention.

### DETAILED DESCRIPTION OF PREFERRED EMBODIMENTS

The present invention provides a packaging method for UV LED to avoid degradation problems resulted by the conventional packaging method in order to improve long-term protection to a UV LED chip, especially to a UV LED chip emitting light with wavelength less than 365 nm, and thus improve operation life of a UV LED chip. It is to be noted that the following descriptions of preferred embodiments of this invention are presented herein for purpose of illustration and description only but not intended to be exhaustive or to be limited to the precise form disclosed.

In the following illustration, the element arranged repeatedly is described in word “one”, “a” or “an” for simpler explanation; and an arrange of number represented by “˜” includes both ends of the numbers as minimum and maximum values. However, one skilled in the art should understand the practical structure and arrangement of each element based on the following illustration and figures provided in the present application. In addition, in the following description, the word “solution” means a mixture of solvent and solute and is in liquid state if there is no other special limitation. The solute can be gas, liquid, or solid, and solvent has to be liquid.

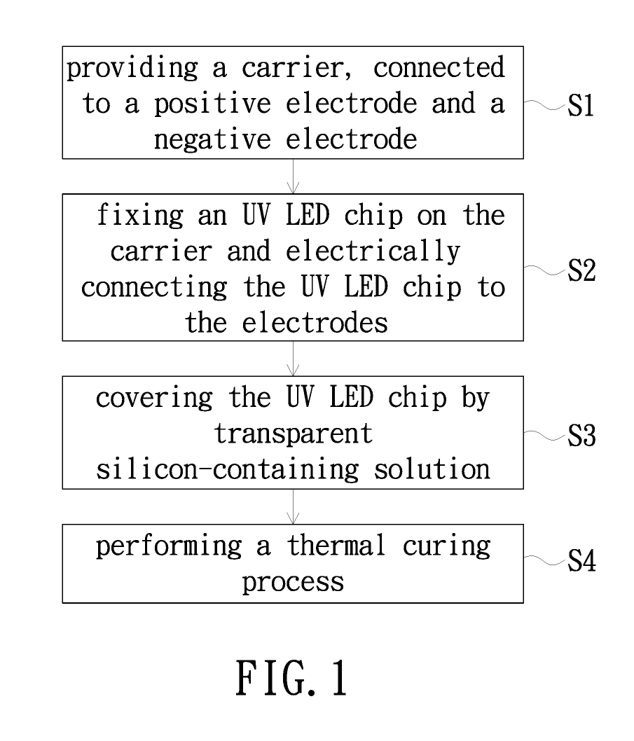

As shown in FIG. 1, the packaging method for UV LED provided by the present invention comprises: step (S1) providing a carrier, connected to a positive electrode and a negative electrode, respectively; step (S2) fixing an UV LED chip on the carrier and electrically connecting the UV LED chip to the electrodes; step (S3) covering the UV LED chip with transparent silicon-containing (preferably silicon-and-oxygen-containing) solution; and step (S4) performing a thermal curing process. In an embodiment of the present invention, the transparent silicon-and-oxygen-containing solution is a homogeneous solution obtained by mixing SOG (spin-on glass) materials and suitable solvent, such as ethanol, ketones, esters, or combination thereof. In different embodiments of the present invention, the covering process of the step (S3) can be performed by dispensing thereof, and then optionally followed by spinning or molding process to improve covering uniformity and flatness. In some embodiments of the present invention, a dielectric layer is optionally formed thereon before fixing the UV LED chip onto the carrier in order to have better protection.

According to the above method, different embodiments of the present invention are provided in the following description for illustration only but not intend to limit the present invention. The packaging method provided by the present invention can be applied to a conventional wire-bonding chip and a flip chip without wire-bonding and is suitable with or without a lead frame structure/a ceramic wall structure.

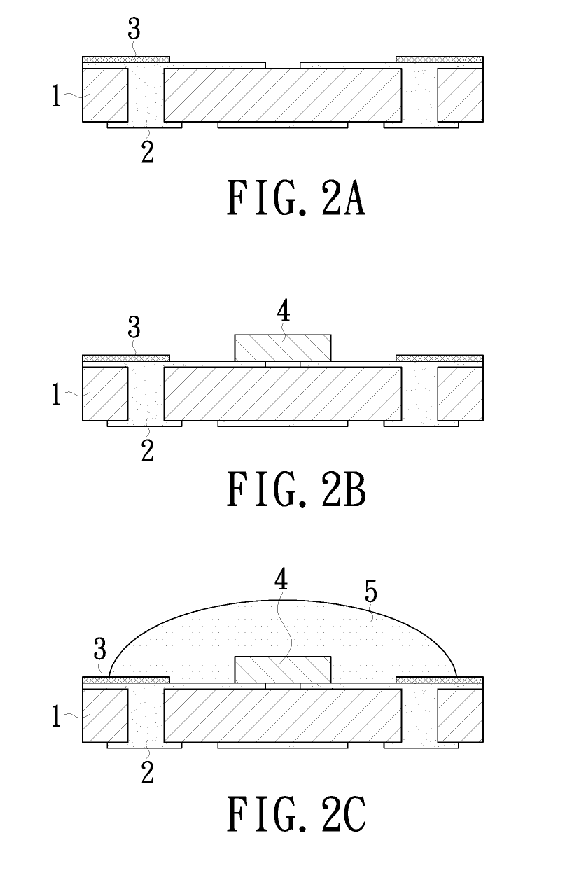

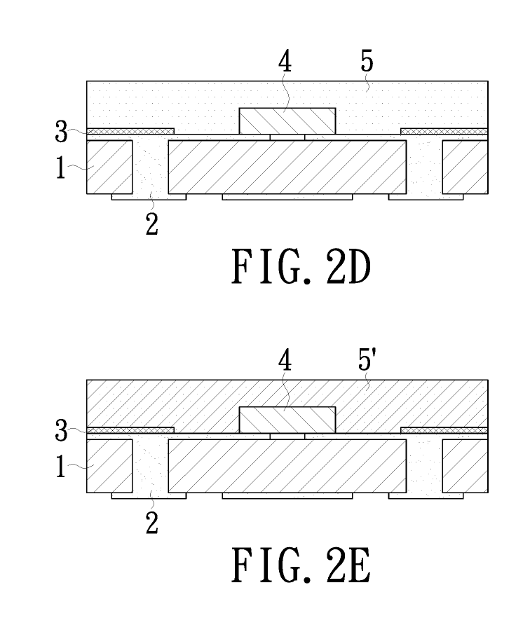

FIGS. 2A-2E are cross-sectional views of different steps according to an embodiment of the present invention following the method provided by the present invention. As shown in FIG. 2A, a carrier 1 is connected to a plurality of electrodes 2, respectively, wherein portions of the electrodes 2 are exposed, respectively, in order to electrically-connect to a chip (not shown) in the following steps, and other portions of the electrodes 2 are respectively covered by a dielectric layer 3 formed thereon for protection and insulation. The carrier 1 in this illustrated embodiment uses a conventional non-transparent substrate. Then as shown in FIG. 2B, an UV LED chip 4 is fixed onto the carrier 1 and electrically-connected to the electrodes 2, respectively, wherein a wavelength of light emitted by the UV LED chip 4 is less than or equal to 365 nm. In the present invention, a packaging structure without a cavity structure is used, and the UV LED chip 4 is a flip chip and no metal wire is needed. As shown in FIG. 2B, the UV LED chip 4 has chip electrodes (no shown) and can be electrically-connected to the electrodes 2 by eutectic bonding or soldering. Then a transparent silicon-and-oxygen-containing solution 5 is dispensed onto the carrier 1 covering the UV LED chip 4. The transparent silicon-and-oxygen-containing solution 5 used in the embodiment is liquid SOG solution obtained by dissolving siloxane into ethanol. After the dispensing process thereof, the transparent silicon-and-oxygen-containing solution 5 is in the central area of the carrier 1 as shown in FIG. 2C (the transparent silicon-and-oxygen-containing solution 5 can cover multiple UV LED chips 4 in actual cases or usage scenarios, thus FIG. 2C is for illustration only). In this embodiment, in order to make the transparent silicon-and-oxygen-containing solution 5 evenly and completely covering the carrier 1, the UV LED chip 4 and the electrodes 2 as shown in FIG. 2D, a spinning process is then performed. Afterward, a thermal curing process is performed under a temperature condition in a range of 300˜600° C. in order to cure the transparent silicon-and-oxygen-containing solution 5 into a siloxane UV protective structure 5′ as shown in FIG. 2E.

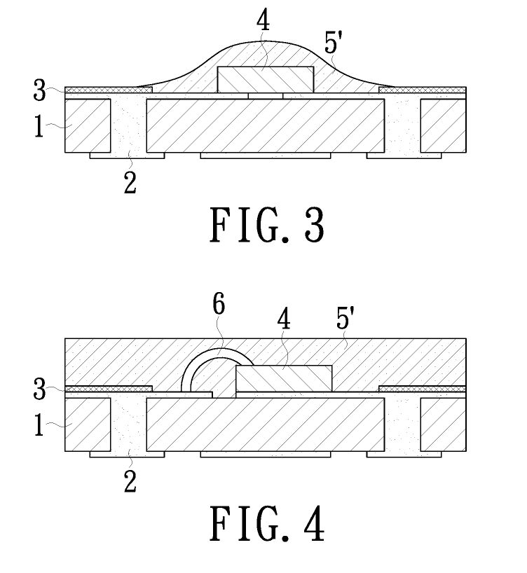

In some embodiments of the present invention which are applying the similar process; however, an amount of the transparent silicon-and-oxygen-containing solution dispensed in the step (S3) is less than sufficient and not enough to evenly cover the entire carrier but only cover the entire UV LED chip and the exposed portion of the electrodes. As shown in FIG. 3, the siloxane UV protective structure 5′ conformally covers the entire UV LED chip 4, exposed portion of the electrodes 2, and optionally portions of the dielectric layer 3. It should be noted that, the siloxane UV protective structure 5′ has to at least cover the entire UV LED chip 4 and exposed portion of the electrodes 2 in order to have better protection.

In other embodiments of the present invention after applying the method as illustrated in FIG. 1, the step (S3) is performed by dispensing and molding process to flatten the transparent silicon-and-oxygen-containing solution 5 and make the transparent silicon-and-oxygen-containing solution 5 to be evenly and entirely covering the carrier 1, the UV LED chip 4, and the electrodes 2 (and the entire dielectric layer 3 in the cases it formed thereon). Cross-sectional views of different steps are similar to those shown in FIGS. 2A-2E and are not shown in additional figures herein. It should be noted that, the molding process is performed under a condition of providing enough amount of the transparent silicon-and-oxygen-containing solution 5 to have been dispensed onto the carrier 1. Moreover, in these embodiments of the present invention, the thermal curing process is performed under a temperature condition in a range of 300˜600° C.

In another embodiment of the present invention, it uses conventional wire-bonding chips applying the packaging method provided above. As shown in FIG. 4, the UV LED chip 4 is electrically-connected to the electrodes 2 through a metal wire 6. In the embodiment using a wire-bonding chip, the transparent silicon-and-oxygen-containing solution 5 has to completely cover the carrier 1, the UV LED chip 4, the electrodes 2, and the metal wires 6 in order to have better protection.

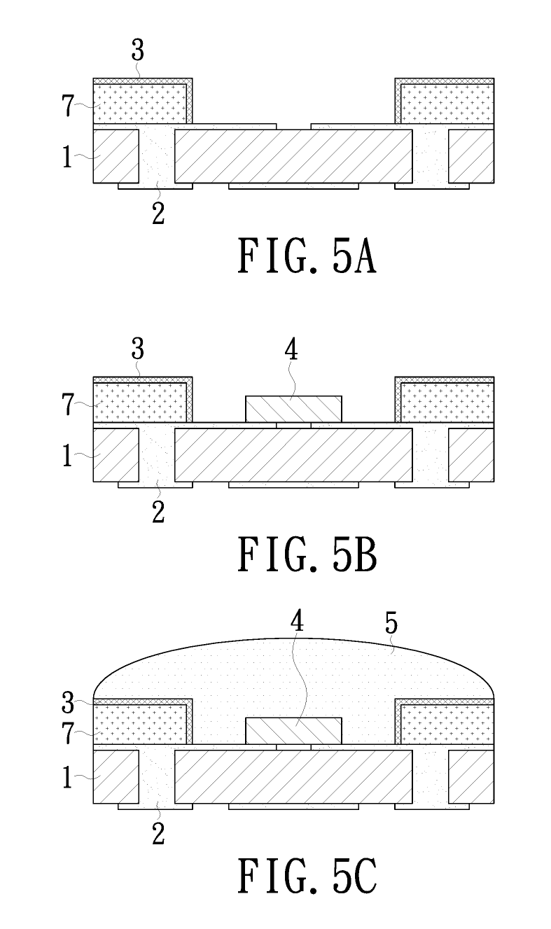

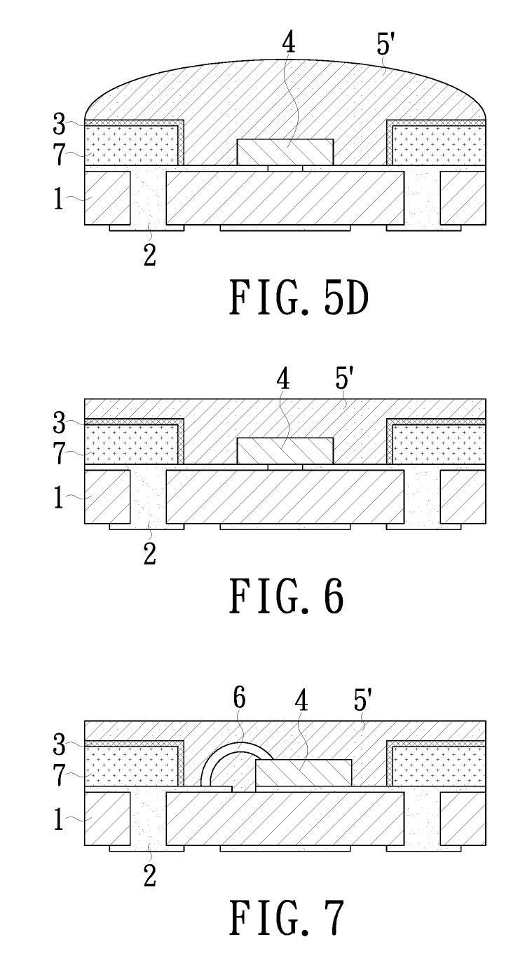

FIGS. 5A-5D are cross-sectional views of different steps applied in another embodiment for packaging method for a flip chip of the present invention, and as for easier illustration and understanding, elements with same properties/functions use same element numbers in the figures. As shown in FIG. 5A, a carrier 1, connected to a plurality of electrodes 2, is provided. A cavity structure 7 is disposed on the carrier 1 exposing a portion of the electrodes 2 (can be directly on the electrodes 2 and/or directly on the carrier 1 depending on different cases). In this embodiment, the cavity structure 7 covers portions of the electrodes 2 and remain portions of the electrodes exposed inside a cavity defined by the cavity structure 7 in order to electrically-connect the UV LED chip 4 and the electrodes 2. The cavity structure 7 in the embodiment is made of ceramic and surrounds the UV LED chip 4 to protect the UV LED chip 4 disposed therein; however, in other embodiments the cavity structure can be a lead frame and/or in other shapes as long as it can provide protection to the UV LED chip 4. Then as shown in FIG. 5B, the UV LED chip 4 is fixed onto the carrier 1 surrounded by the cavity structure 7 and electrically-connected to the electrodes 2. A dielectric layer 3 is optionally disposed on the cavity structure 7 in order to improve the protection. In this embodiment, the dielectric layer 3 covers top and inner surfaces of the cavity structure 7; however, it is not intended to limit the present invention. In other embodiments, there is no dielectric layer 3 used; the dielectric layer 3 covers only the top surface of the cavity structure 7; or the dielectric layer 3 covers the entire cavity structure 7. In some embodiments of the present invention, the cavity structure 7 optionally includes light reflective materials for better emitting effects.

In the above mentioned embodiment, the packaging structure has the cavity structure 7 applied to a flip chip, as shown in FIG. 5B. The UV LED chip 4 has chip electrodes (not shown) and electrically connected to the electrodes 2 by eutectic bonding, soldering or direct contact. Then the transparent silicon-and-oxygen-containing solution 5 is dispensed onto the carrier 1 covering the UV LED chip 4. A difference between this embodiment and other embodiments without cavity structure 7 as illustrated above is that, the transparent silicon-and-oxygen-containing solution 5 possibly covers in central area or a couple of areas on the carrier 1 after the dispensing process, and a molding/spinning process is performed to make the transparent silicon-and-oxygen-containing solution 5 evenly and completely covering the carrier 1 and the UV LED chip 4; however, in this embodiment, the cavity structure 7 surrounds individual UV LED chip 4 and therefore forms individual cavity, and thus in the dispensing process, the transparent silicon-and-oxygen-containing solution 5 is dispensed into individual cavity covering the UV LED chip 4 and the cavity structure 7, as shown in FIG. 5C. The transparent silicon-and-oxygen-containing solution 5 with a curved top surface thereof is formed individually covering the individual UV LED chip 4 and the individual cavity structure 7. Finally a thermal curing process is performed under a temperature condition of 300˜600° C. in order to dry the transparent silicon-and-oxygen-containing solution 5 into a siloxane UV protective structure 5′, as shown in FIG. 5D.

In other embodiments (also with cavity structure 7 on the carrier 1) of the present invention following similar process, after the dispensing process to form the (convex-shaped) transparent silicon-and-oxygen-containing solution 5 as shown in FIG. 5C, a spinning process is optionally performed in order to flatten the transparent silicon-and-oxygen-containing solution 5, and to make the transparent silicon-and-oxygen-containing solution 5 evenly and completely covering the carrier 1, the UV LED chip 4, the electrodes 2, the cavity structure 7 and the dielectric layer 3. Then the thermal curing process is performed to cure the transparent silicon-and-oxygen-containing solution 5 into a siloxane UV protective structure 5′, as shown in FIG. 6.

In another embodiment of the present invention, it applies similar process as illustrated in FIGS. 5A-5C and above description but with additional molding process after the dispensing process, instead of the spinning process, before the thermal curing process in order to flatten the transparent silicon-and-oxygen-containing solution 5 and to make the transparent silicon-and-oxygen-containing solution 5 evenly and completely covering the carrier 1, the UV LED chip 4, the electrodes 2, the wall structure 7 and the dielectric layer 3. The final cross-sectional view is similar to the structure as shown in FIG. 6, and no extra figure is shown for this embodiment; however, it is for illustration only but not intending to limit the present invention.

In another embodiment of the present invention, a wire-bonding chip and a cavity structure 7 are applied to the method provided by the present invention. As shown in FIG. 7, a chip electrode (not shown) is electrically connected to the electrode 2 via at least one metal wire 6, and another chip electrode is electrically connected to another electrode 2 by direct contact. In those embodiments using wire-bonding chips, the transparent silicon-and-oxygen-containing solution 5 has to completely cover the carrier 1, the UV LED chip 4, electrodes 2, and the metal wire 6 for better protection.

Therefore, the present invention provides a packaging method for UV LED, which is suitable for any conventional LED chip with common ranges of wavelength, especially for UV LED chip with wavelength less than 365 nm. The above embodiments are for illustration only but not intending to limit the present invention. The present invention provides the packaging method is able to avoid degradation problems resulted by the conventional packaging method and thus improve service life of a UV LED chip.

While the invention has been described in terms of what is presently considered to be the most practical and preferred embodiments, it is to be understood that the invention needs not be limited to the disclosed embodiment. On the contrary, it is intended to cover various modifications and similar arrangements included within the spirit and scope of the appended claims which are to be accorded with the broadest interpretation so as to encompass all such modifications and similar structures.

What is claimed is:

1. A packaging method for ultraviolet light emitting diode, comprising steps of:
(S1) providing a carrier, connected to an electrode;
(S2) fixing a UV LED chip on the carrier and electrically-connecting the UV LED chip to the electrode;
(S3) covering the UV LED chip with a transparent silicon-containing solution; and
(S4) performing a thermal curing process.

2. The packaging method for ultraviolet light emitting diode according to claim 1, wherein the transparent silicon-containing solution is made of spin-on glass (SOG).

3. The packaging method for ultraviolet light emitting diode according to claim 1, wherein the step (S3) comprises sub-steps:
(S3A) dispensing the transparent silicon-containing solution onto the carrier to cover the UV LED chip; and
(S3B) spinning the carrier to flatten the transparent silicon-containing solution and make the transparent silicon-containing solution completely covering the carrier, the UV LED chip, and the electrode.

4. The packaging method for ultraviolet light emitting diode according to claim 1, wherein the step (S3) comprises sub-steps:
(S3A′) dispensing the transparent silicon-containing solution onto the carrier to cover the UV LED chip; and
(S3B′) performing a molding process to flatten the transparent silicon-containing solution and make the transparent silicon-containing solution completely covering the carrier, the UV LED chip and the electrode.

5. The packaging method for ultraviolet light emitting diode according to claim 1, after the step (S1) and before the step (S2), further comprising:
forming a dielectric layer covering a portion of the electrode and exposing a portion of the electrode.

6. The packaging method for ultraviolet light emitting diode according to claim 5, wherein the step (S3) comprises sub-steps:
(S3a) dispensing the transparent silicon-containing solution onto the carrier to cover the UV LED chip; and
(S3b) spinning the carrier to make the transparent silicon-containing solution completely covering the UV LED chip and the exposed portion of the electrode.

7. The packaging method for ultraviolet light emitting diode according to claim 6, wherein the UV LED chip is a flip chip.

8. The packaging method for ultraviolet light emitting diode according to claim 7, after the sub-step (S3b), wherein the transparent silicon-containing solution conformally covers the UV LED chip and the exposed portion of the electrode and exposes a portion of the dielectric layer.

9. The packaging method for ultraviolet light emitting diode according to claim 7, after the sub-step (S3b), wherein the transparent silicon-containing solution is flattened and completely covers the dielectric layer.

10. The packaging method for ultraviolet light emitting diode according to claim 6, wherein the UV LED chip is electrically-connected to the electrode by a metal wire and the transparent silicon-containing solution is flattened and completely covers the metal wire after the sub-step (S3b).

11. The packaging method for ultraviolet light emitting diode according to claim 5, wherein the step (S3) comprises sub-steps:
(S3a′) dispensing the transparent silicon-containing solution onto the carrier to cover the UV LED chip; and
(S3b′) performing a molding process to flatten the transparent silicon-containing solution and make the transparent silicon-containing solution completely covering the UV LED chip and the exposed portion of the electrode.

12. The packaging method for ultraviolet light emitting diode according to claim 11, wherein the UV LED chip is a flip chip.

13. The packaging method for ultraviolet light emitting diode according to claim 11, wherein the UV LED chip is electrically-connected to the electrode by a metal wire and the transparent silicon-containing solution is completely covering the metal wire after the sub-step (S3b′).

14. The packaging method for ultraviolet light emitting diode according to claim 1, wherein in the step (S1), a cavity structure is disposed on the carrier exposing a portion of the electrode.

15. The packaging method for ultraviolet light emitting diode according to claim 14, after the step (S1) and before the step (S2), further comprising:
forming a dielectric layer covering a portion of the cavity structure and exposing the portion of the electrode.

16. The packaging method for ultraviolet light emitting diode according to claim 14, wherein the step (S3) is performed by only dispensing the transparent silicon-containing solution onto the UV LED chip to form a convex structure of the transparent silicon-containing solution covering the UV LED chip, the exposed portion of the electrode and the cavity structure.

17. The packaging method for ultraviolet light emitting diode according to claim 14, wherein the step (S3) comprises sub-steps:
(S3a″) dispensing the transparent silicon-containing solution onto the carrier to cover the UV LED chip and the cavity structure; and
(S3b″) spinning the carrier to flatten the transparent silicon-containing solution and make the transparent silicon-containing solution completely covering the carrier, the UV LED chip, the electrode, and the cavity structure.

18. The packaging method for ultraviolet light emitting diode according to claim 17, wherein the UV LED chip is a flip chip.

19. The packaging method for ultraviolet light emitting diode according to claim 17, wherein the UV LED chip is electrically-connected to the electrode by a metal wire and the transparent silicon-containing solution is completely covering the metal wire after the sub-step (S3b″).

20. The packaging method for ultraviolet light emitting diode according to claim 14, wherein the step (S3) comprises:
(S3a′″) dispensing the transparent silicon-containing solution onto the carrier to cover the UV LED chip; and
(S3b′″) performing a molding process to flatten the transparent silicon-containing solution and make the transparent silicon-containing solution completely covering the carrier, the UV LED chip, the electrode, and the cavity structure.

21. The packaging method for ultraviolet light emitting diode according to claim 20, wherein the UV LED chip is a flip chip.

22. The packaging method for ultraviolet light emitting diode according to claim 20, wherein the UV LED chip is electrically-connected to the electrode by a metal wire and the transparent silicon-containing solution is completely covering the metal wire after the sub-step (S3b′″).

23. The packaging method for ultraviolet light emitting diode according to claim 1, wherein the step (S4) is performed under a temperature condition in a range of 300˜600° C.
